(19) United States
(12) Patent Application Publication
(10) Pub. No.: US 2026/0082549 A1
(43) Pub. Date: Mar. 19, 2026

(54) SEMICONDUCTOR STRUCTURE

(71) Applicant: Fujian Jinhua Integrated Circuit Co., Ltd., Fujian (CN)

(72) Inventors: LI-WEI FENG, Fujian (CN); Yirong XU, Fujian (CN); Janbo ZHANG, Fujian (CN)

(73) Assignee: Fujian Jinhua Integrated Circuit Co., Ltd., Fujian (CN)

(21) Appl. No.: 19/242,886

(22) Filed: Jun. 18, 2025

(30) Foreign Application Priority Data
Sep. 14, 2024 (CN) 202411295452.7

(51) Int. Cl. H10B 12/00

(52) U.S. Cl. CPC H10B 12/482; H10B 12/34; H10B 12/485; H10B 12/50

(57) ABSTRACT

Embodiments of the present disclosure provide a semiconductor structure, which relates to the field of semiconductor technologies. The semiconductor structure includes a substrate including an active region defined by a shallow trench isolation structure; a plurality of word line structures disposed in the substrate, crossing the active region and extending in a second direction; a plurality of bit line structures disposed on the substrate and extending in a first direction which intersects the second direction. Each bit line structure includes: a first portion crossing the active region and the word line structures; a third portion disposed on the shallow trench isolation structure; and a second portion whose two ends directly contact the first portion and the third portion, respectively. In the second direction, a width of the second portion is smaller than widths of the first portion and the third portion.

### CROSS-REFERENCE TO RELATED APPLICATION

This application claims priority to Chinese Patent Application No. 202411295452.7, filed on Sep. 14, 2024, which is hereby incorporated by reference in its entirety.

### TECHNICAL FIELD

Embodiments of the present application relate to the field of semiconductor technologies and, in particular, to a semiconductor structure component.

### BACKGROUND

With the development of various electronic products towards miniaturization, the design of dynamic random access memory (DRAM) is gradually developing towards high integration. In the related art, a substrate in a semiconductor memory device generally includes a memory region and a peripheral circuit region, both the storage region and the peripheral circuit region are provided with a bit line (BL).

However, the bit line disposed in the peripheral circuit region is prone to tilt or bend, which even causes adjacent bit lines to be connected with each other, resulting in short-circuit and reducing the yield of the semiconductor memory device.

### SUMMARY

To address the above problems, embodiments of the present application provide a semiconductor structure, which can prevent or even avoid the inclination of the bit line structure and improve the yield of the semiconductor structure.

In order to achieve the on purpose, the embodiments of the present application provide the following technical solutions.

An embodiment of the present application provides a semiconductor structure including a substrate, a plurality of word line structures and a plurality of bit line structures. The substrate includes an active region defined by a shallow trench isolation structure. The plurality of word line structures are disposed in the substrate, cross the active region and extend in a second direction. The plurality of bit line structures are disposed on the substrate and extend in a first direction, and the first direction intersects the second direction. Each bit line structure includes: a first portion crossing the active region and the word line structures; a third portion disposed on the shallow trench isolation structure; a second portion whose two ends directly contact the first portion and the third portion, respectively. In the second direction, a width of the second portion is smaller than widths of the first portion and the third portion.

In a possible implementation, the width of the first portion is smaller than the width of the third portion.

In a possible implementation, the width is a maximum width, or the width is an average width.

In a possible implementation, at least one side of the third portion protrudes from the second portion of the bit line structure in the second direction.

In a possible implementation, both sides of the third portion protrude from the second portion in the second direction.

In a possible implementation, along a direction perpendicular to the substrate, a top surface of the third portion is lower than a top surface of the second portion, or a top surface of the third portion is flush with a top surface of the second portion.

In a possible implementation, a shape of the third portion projected on the substrate includes a polygon, a circle, or an ellipse.

In a possible implementation, in a direction that is away from the first portion of the bit line structure and along the first direction, a size of the third portion in the second direction initially increases and then decreases.

In a possible implementation, at least one side of the first portion protrudes from the second portion in the second direction.

In a possible implementation, a distance between adjacent third portions is a first distance L1, and a distance between adjacent first portions is a second distance L2. The first distance L1 is greater than the second distance L2.

In a possible implementation, a ratio of the first distance L1 to the second distance L2 is 1 to 1.5.

In a possible implementation, the semiconductor structure further includes a dummy bit line structure arranged at one side of the bit line structures in the second direction. In the first direction, the third portion includes a first end and a second end which are oppositely arranged, and the first end is connected to the second portion. An end of the dummy bit line structure facing the third portion in the first direction is disposed at a joint between the first portion and the second portion of the bit line structure, or an end of the dummy bit line structure facing the third portion in the first direction is disposed between the first end and the second end.

In a possible implementation, a first contact plug is arranged between first portions of adjacent bit line structures. The first contact plug disposed at an outermost edge in the first direction has a fourth distance L4 from the third portion of the bit line structure, and the first contact plug has a preset width W4. A ratio of the fourth distance L4 to the preset width W4 is greater than 4.

In the semiconductor structure provided by the embodiments of the present application, the bit line structure includes a third portion which is disposed on the shallow trench isolation structure, and the width of the third portion is greater than the width of the second portion. In this way, the third portion is supported by the shallow trench isolation structure, and the width of the third portion is greater than the width of the second portion, so that the third portion has a more stable support and optimized stress distribution. This enables the third portion to exert a traction effect on the second portion, preventing the second portion from inclining or bending. Consequently, this solution helps avoiding short circuit on the connection between adjacent bit line structures and improving the yield of the semiconductor structure.

In addition to the technical problems solved by the embodiments of the present application, the technical features constituting the technical solutions and the beneficial effects brought by the technical features of these technical solutions described above, other technical problems solved by the semiconductor structure provided by the embodiments of the present application, other technical features included in the technical solutions and the beneficial effects brought by these technical features will be further explained in detail in specific implementations.

### BRIEF DESCRIPTION OF THE DRAWINGS

In order to illustrate technical solutions in the embodiments of the present application or the prior art more clearly, accompanying drawings that need to be used in description of the embodiments or the prior art will be briefly introduced below. It is obvious that the accompanying drawings in the following description are some embodiments of the present disclosure, and for those of ordinary skill in the art, other accompanying drawings may also be acquired according to these accompanying drawings without paying any creative efforts.

FIG. 1 is a structural schematic diagram I of a semiconductor structure provided by an embodiment of the present application.

FIG. 2 is a sectional view along an A-A direction shown in FIG. 1.

FIG. 3 is a structural schematic diagram II of a semiconductor structure provided by an embodiment of the present application.

FIG. 4 is a structural schematic diagram III of a semiconductor structure provided by an embodiment of the present application.

FIG. 5 is a structural schematic diagram IV of a semiconductor structure provided by an embodiment of the present application.

FIG. 6 is a sectional view along a B-B direction shown in FIG. 5.

FIG. 7 is a sectional view along a C-C direction shown in FIG. 5.

FIG. 8 is a structural schematic diagram V of a semiconductor structure provided by an embodiment of the present application.

FIG. 9 is a sectional view along a D-D direction shown in FIG. 8.

FIG. 10 is a structural schematic diagram VI of a semiconductor structure provided by an embodiment of the present application.

FIG. 11 is a sectional view along an E-E direction shown in FIG. 10.

### DESCRIPTION OF THE EMBODIMENTS

With the development of science and technology, a semiconductor integrated circuit are trending towards small size design and high-density arrangement. Based on this, in order to further reduce a width of a bit line structure, a portion of the bit line structure disposed in a peripheral circuit region is generally provided with a smaller width. This results in a large depth-to-width ratio for the bit line structure in the peripheral circuit region, making the bit line structure prone to tilting or bending, and even causing adjacent bit line structures to be connected with each other, which results in short circuit and reduces the yield of the semiconductor structure.

In view of the on technical problems, an embodiment of the present application provides a semiconductor structure, the bit line structure includes a third portion which is disposed on the shallow trench isolation structure, and the width of the third portion is greater than the width of the second portion. In this way, the third portion is supported by the shallow trench isolation structure, and is matched with the width of the third portion being greater than the width of the second portion, so that the third portion has a more stable support and optimized stress distribution. This enables the third portion to exert a traction effect on the second portion, preventing the second portion from inclining or bending. Consequently, this solution helps avoiding short circuit on the connection between adjacent bit line structures and improving the yield of the semiconductor structure.

In order to make the foregoing objects, features and advantages of the embodiments of the present application more obvious and easy to understand, technical solutions in the embodiments of the present application will be clearly and completely described below with reference to the accompanying drawings in the embodiments of the present application. It is obvious that the described embodiments are only some of the embodiments of the present application, and not all of the embodiments. Based on the embodiments in the present application, all other embodiments obtained by those of ordinary skill in the art in the art without making creative effort, all belong to the protection scope of the present application.

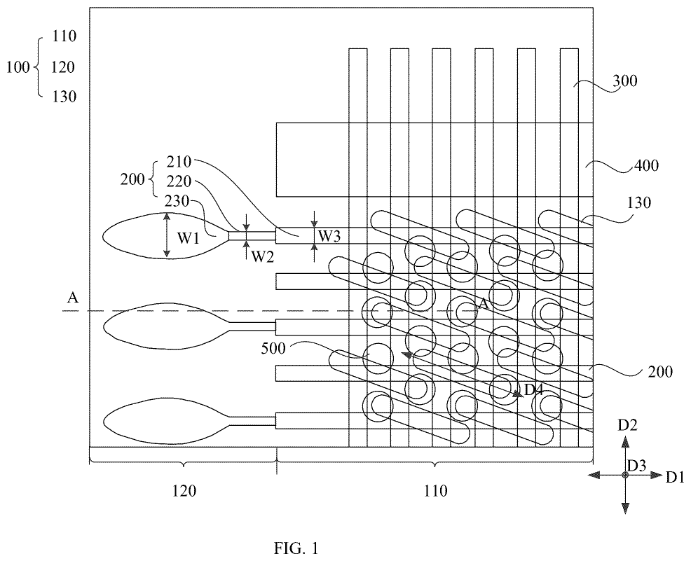

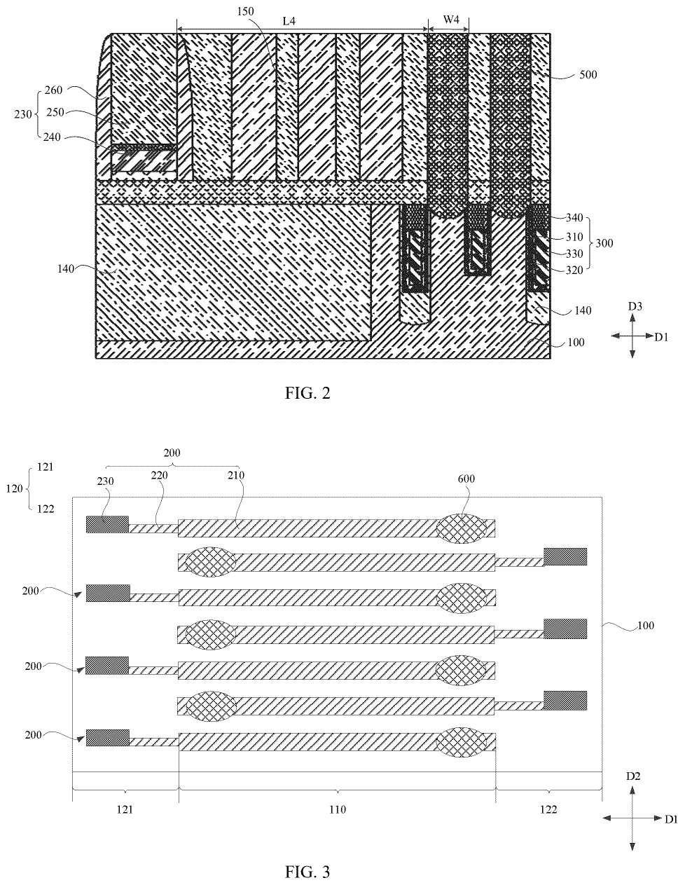

For ease of explanation and assistance in understanding the semiconductor structure provided by the present application, refer to FIG. 1 and FIG. 2, which show spatial reference directions such as a first direction D1, a second direction D2, a third direction D3, and a fourth direction D4. The first direction D1 and the second direction D2 are generally parallel to a surface of a substrate 100, and the third direction D3 is generally perpendicular to the surface of the substrate 100. The third direction D3 herein can also be referred to as a vertical direction. The first direction D1, the second direction D2, and the fourth direction D4 can also be referred to as horizontal directions.

The overall structure of the semiconductor structure is described below with reference to the drawings.

Referring to FIG. 1 and FIG. 2, an embodiment of the present application provides a semiconductor structure that includes a substrate 100. The substrate 100 serves as a main body-carrying component of the semiconductor structure for carrying components disposed thereon. Among them, the substrate 100 may be any substrate 100 suitable for manufacturing semiconductor elements, such as a silicon (Si) substrate, an epitaxial silicon (epi-Si) substrate, a silicon germanium (SiGe) substrate, a silicon carbide (SiC) substrate, or a silicon-on-insulator (SOI) substrate, but is not limited thereto.

The substrate 100 includes an active region 130, the active region 130 is defined by a shallow trench isolation (STI) structure and the active region 130 may extend along the fourth direction D4. The fourth direction D4 may be a direction different from the first direction D1 and the second direction D2, but located in the same plane. The fourth direction D4 forms an inclined angle with both the first direction D1 and the second direction D2 respectively. That is, the active region 130 is obliquely arranged relative to the first direction D1 and the second direction D2.

It should be understood that, in this embodiment, there may be a plurality of active regions 130, and the plurality of active regions 130 are arranged in an array. The shallow trench isolation structure 140 may isolate the plurality of active regions 130 to ensure that the active regions 130 are independent from each other. Illustratively, a shallow trench is formed in the substrate 100 through a patterned fabrication process, and a shallow trench isolation structure 140 is formed in the shallow trench, thereby defining the plurality of active regions 130 on the substrate 100 separated by the shallow trench isolation structure 140. The patterned fabrication process may be a self-aligned double patterning (SADP) process or self-aligned quadruple patterning (SAQP) process.

In some embodiments, the shallow trench isolation structure 140 may be made of an insulating material, and the shallow trench isolation structure 140 may also be a laminated structure. Illustratively, the shallow trench isolation structure 140 includes a first isolation layer, a second isolation layer, and a third isolation layer which are arranged in a stacked manner. Among them, the first isolation layer is arranged on an inner wall of the shallow trench, the second isolation layer is arranged on the first isolation layer, the third isolation layer is arranged on the second isolation layer and completely fills a region surrounded by the second isolation layer. Materials of the first isolation layer and the third isolation layer may be the same or different. For example, the materials of the first isolation layer and the third isolation layer both include silicon oxide, and a material of the second isolation layer includes silicon nitride, so that the shallow trench isolation structure 140 has an “ONO” structure. With this arrangement, the isolation effect of the shallow trench isolation structure 140 can be improved, so that the active regions 130 are independent from each other. It should be understood that the drawings provided by the embodiments only indicate a position of the shallow trench isolation structure 140, and do not show all its specific film layers.

Please continue to refer to FIG. 1 and FIG. 2, the semiconductor structure further includes a plurality of word line structures 300. The plurality of word line structures 300 are disposed in the substrate 100 and arranged at intervals along the first direction D1. The word line structure 300 crosses the active region 130 and extends in the second direction D2. Here, the second direction D2 may intersect the first direction D1. Illustratively, in the same plane, the second direction D2 may be perpendicular to the first direction D1.

Each word line structure 300 is connected to the plurality of active regions 130 arranged at intervals along the second direction D2, so that each word line structure 300 is connected to a plurality of transistors (not shown in the figure) arranged at intervals along the second direction D2, thereby simplifying the circuit design of the semiconductor structure, reducing the complexity and length of wiring, and further improving the operation speed and efficiency of the semiconductor structure.

Please refer to FIG. 2, the word line structure 300 may include a dielectric layer 310, a barrier layer 320, a conductive layer 330 and an insulating layer 340. In this embodiment, the word line structure is a buried structure, thus a trench is generally required to be formed in the substrate 100 during the fabrication process. The trench extends along the second direction D2 and crosses the plurality of active regions 130 arranged along the second direction D2. The dielectric layer 310 covers an inner wall of the trench, the barrier layer 320 is arranged on the dielectric layer 310, and a top surface of the barrier layer 320 is lower than a top surface of the dielectric layer 310. The conductive layer 330 is arranged on the barrier layer 320 and completely fills a region surrounded by the barrier layer 320. The insulating layer 340 is arranged on the conductive layer 330 and connected to an inner wall of the dielectric layer 310.

A material of the dielectric layer 310 includes silicon oxide, a material of the barrier layer 320 includes titanium nitride, and a material of the conductive layer 330 includes tungsten, a material of the insulating layer 340 includes silicon nitride. The barrier layer 320 is used to prevent the conductive material in the conductive layer 330 from diffusing into the substrate 100, thereby improving the performance of the semiconductor structure. It should be understood that a portion of the word line structure 300 disposed in the active region 130 may constitute the gate structure of the transistor.

Please refer to FIG. 5 to FIG. 11, the semiconductor structure further includes a plurality of bit line structures 200, and the plurality of bit line structures 200 are disposed on the substrate 100. The plurality of bit line structures 200 are arranged at intervals along the second direction D2 and extend along the first direction D1. It should be noted that when the semiconductor structure is a semiconductor memory device, the bit line structure 200 is used to connect either the source or the drain of the transistor.

Among them, each bit line structure 200 includes a first portion 210, a second portion 220 and a third portion 230. The first portion 210 crosses the active region 130 and the word line structure 300, the third portion 230 is disposed on the shallow trench isolation structure 140, and both ends of the second portion 220 directly contact the first portion 210 and the third portion 230, respectively. In other words, the second portion 220 is arranged between the first portion 210 and the third portion 230 for connecting the first portion 210 and the third portion 230.

In the second direction, a width of the second portion 220 is smaller than a width of the first portion 210 and a width of the third portion 230. In other words, the width of the third portion 230 is greater than the width of the second portion 220. In this embodiment, the third portion 230 is supported by the shallow trench isolation structure 140, and is matched with the width of the third portion 230 being greater than the width of the second portion 220, so that the third portion 230 has a more stable support and optimized stress distribution. This enables the third portion 230 to exert a traction effect on the second portion 220, preventing the second portion 220 from inclining or bending, thereby avoiding short circuit on the connection between adjacent bit line structures 200 and improving the yield of the semiconductor structure. It should be noted that the width in this embodiment refers to an average width. On the premise that the width of the second portion 220 is smaller than the width of the first portion 210 and the width of the third portion 230, there may be other implementations of the width of the first portion 210 and the width of the second portion 220, and the width of the first portion 210 and the width of the third portion 230. Illustratively, the width of the first portion 210 is smaller than the width of the third portion 230, but greater than the width of the second portion 220. The first portion 210 crosses the active region 130 and the word line structure 300, and its smaller width can optimize the current density distribution, reduce the current concentration effect, and reduce the risk of electro migration, thereby improving the reliability and life of the semiconductor structure.

It should be noted that the width described in this embodiment can be selected according to the shape of the bit line structure 200. In an example, when the bit line structure 200 has a regular shape, for example, the bit line structure 200 has a strip shape with equal width, the width of the bit line structure 200 may be a width at any position. In another example, when the bit line structure 200 has an irregular shape, the width may be the maximum width, or, the width may be an average width.

In addition, positions in which the first portion 210, the second portion 220, and the third portion 230 of the bit line structure 200 are disposed are related to the partition of the substrate 100. For example, the substrate 100 may include a first region 110 and a second region 120. The first region 110 and the second region 120 are adjacent to each other, the first region 110 is used for arrangement of a memory unit, and the second region 120 may be a peripheral circuit region which provides necessary control and interface functions.

At least the first portion 210 is disposed in the first region 110, that is, the first portion 210 may be disposed in the first region 110, or the first portion 210 and the second portion 220 may be disposed in the first region 110. The third portion 230 is disposed in the second region 120. Considering that the second region 120 is a peripheral circuit region and contains a relatively smaller number of semiconductor devices, therefore, the width of the third portion 230 is the largest in this embodiment. This can increase the traction force of the third portion 230 on the second portion 220 as much as possible, thereby reducing or even avoiding the tilt of the bit line structure 200.

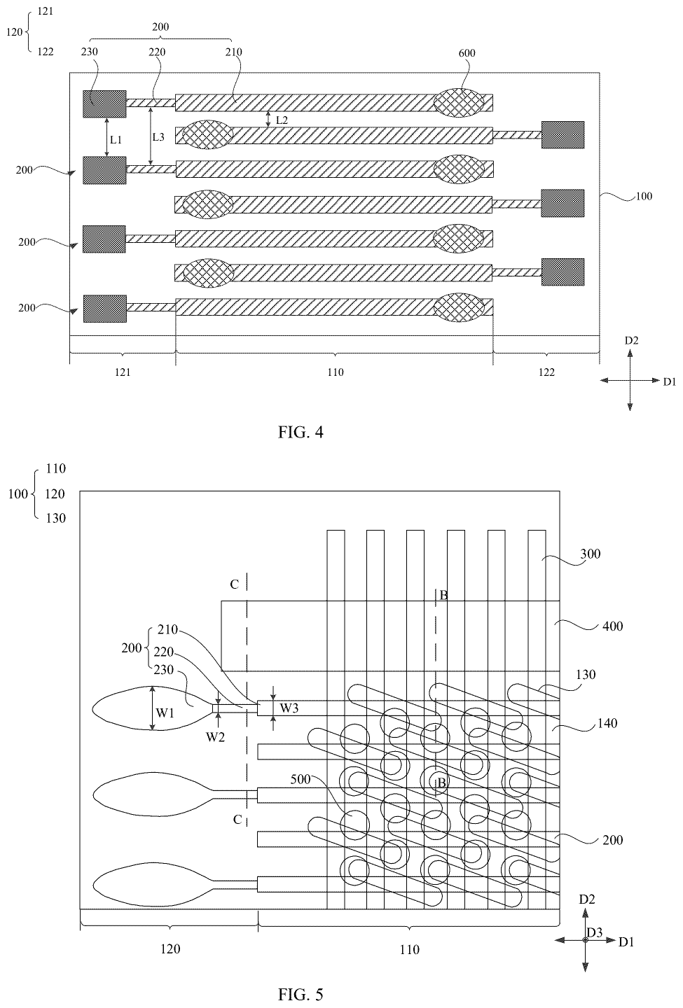

In a possible implementation, please refer to FIG. 3 and FIG. 4, in the second direction D2, at least one side of the third portion 230 protrudes from the second portion 220 of the bit line structure 200. In an example, taking the orientation in FIG. 3 as an example, one side of the third portion 230 protrudes from the second portion 220 of the bit line structure 200, a rear side of the third portion 230 protrudes from the second portion 220, or a front side of the third portion 230 protrudes from the second portion 220. In another example, please refer to FIG. 4, both sides of the third portion 230 protrude from the second portion 220 in the second direction D2.

The shape of the third portion 230 may be arranged according to the layout direction of adjacent bit line structures 200. When a distance between adjacent bit line structures 200 in the second direction D2 is larger, both sides of the third portion 230 can protrude from the second portion 220, this allows the area of the third portion 230 to be increased as much as possible, thus providing a larger contact area and support force, enhancing the mechanical stability of the bit line structure 200, dispersing mechanical stress and reducing the risk of deformation or breakage of the bit line structure 200. When a distance between adjacent bit line structure 200 in the second direction D2 is smaller, one side of the third portion 230 may protrude from the second portion 220 of the bit line structure 200.

In any two adjacent bit line structures 200, their third portions 230 may be disposed on the same side or on different sides. Illustratively, in any two adjacent bit line structures 200, two bit line structures 200 are arranged in central symmetry. That is, the two third portions 230 are disposed on different sides.

To describe any two adjacent bit line structures 200 in detail, the second region 120 may be further refined. For example, the second region 120 includes a first sub-region 121 and a second sub-region 122. The first sub-region 121 and the second sub-region 122 are respectively arranged on both sides of the first region 110 in the first direction D1, and are connected to the first region 110. It should be understood that, in this embodiment, the second region 120 is not limited to being arranged on both sides of the first region 110 in the first direction D1, it may also be arranged on at least one side of the first region 110 in the second direction D2, and can be freely arranged according to the actual structure of the semiconductor structure.

In any two adjacent bit line structures 200, the third portion 230 of bit line structure 200 is disposed within the first sub-region 121, the third portion 230 of the other bit line structure 200 is disposed within the second sub-region 122. In other words, the two adjacent third portions 230 are arranged in a staggered manner, and on the premise of increasing the area of the third portions 230 as much as possible, the distance between the adjacent third portions 230 can also be increased to reduce the parasitic capacitance generated between the adjacent bit line structures 200, thereby improving the performance of the semiconductor structure.

In a possible implementation, along a direction perpendicular to the substrate 100, a top surface of the third portion 230 is lower than a top surface of the second portion 220; alternatively, the top surface of the third portion 230 is flush with the top surface of the second portion 220. In this embodiment, the third portion 230 also serves as a protective sidewall, the third portion 230 may provide additional support for the side of the second portion 220 in the first direction D1. This support reduces or even avoids the inclination of the second portion 220 along the first direction D1, thereby improving the yield of the semiconductor structure.

It should be noted that the shape of the third portion 230 may be regular or irregular. Illustratively, a shape projected by the third portion 230 on the substrate 100 includes a polygon, a circle, or an ellipse. When the shape projected by the third portion 230 on the substrate 100 is a polygon, the third portion 230 can be a quadrilateral, pentagon, or other polygon.

By optimizing the shape design of the third portion 230 and utilizing its advantages in regular or irregular shape, this embodiment can effectively improve design flexibility, optimize space utilization, enhance mechanical stability, thereby improving the overall performance and reliability of the semiconductor structure.

Please continue to refer to FIG. 1, in a direction away from the first portion 210 of the bit line structure 200 along the first direction, a size of the third portion 230 in the second direction shows a trend of increasing first and then decreasing. By limiting the size of the third portion 230 in the second direction, this embodiment can better optimize stress distribution, gradually dispersing and absorbing stress, reducing stress concentration points, thereby reducing the risk of deformation and fracture of the bit line structure 200, and enhancing the stability of the semiconductor structure. In addition, in a direction away from the first portion 210 of the bit line structure 200, the third portion 230 exhibits a decreasing trend. This can also reduce the parasitic capacitance generated between third portions 230 of adjacent bit line structures 200.

In this embodiment, the width of the first portion 210 is also greater than that of the second portion 220. This may be achieved by at least one side of the first portion 210 protruding from the second portion 220 in the second direction, to reduce the resistance of the first portion 210, thereby increasing the speed of signal transmission, reducing signal delay and distortion, and enhancing the signal integrity and transmission performance of the semiconductor structure.

Please continue to refer to FIG. 4, a distance between adjacent third portions 230 is a first distance L1. A distance between adjacent first portions 210 is a second distance L2. The first distance L1 is greater than the second distance L2. Illustratively, a ratio of the first distance L1 to the second distance L2 is 1 to 1.5, or in other words, the first distance L1 is between 1 and 1.5 times the second distance L2. For example, the ratio of the first distance L1 to the second distance L2 is 1.0, 1.1, 1.2, 1.3, 1.4, or 1.5. A larger first distance L1 may offer more space for arranging the peripheral circuit and other functional modules, while a smaller second distance L2 may improve the integration level of memory units and realize high-density arrangement, and facilitate the development of the semiconductor structure towards integration and miniaturization.

In other embodiments, the distance between adjacent third portions 230 and a distance between adjacent second portions 220 can also be limited. For example, please refer to FIG. 4, the distance between adjacent second portions 220 is a third distance L3. The third distance L3 is greater than the first distance L1, and the first distance L1 is greater than the second distance L2.

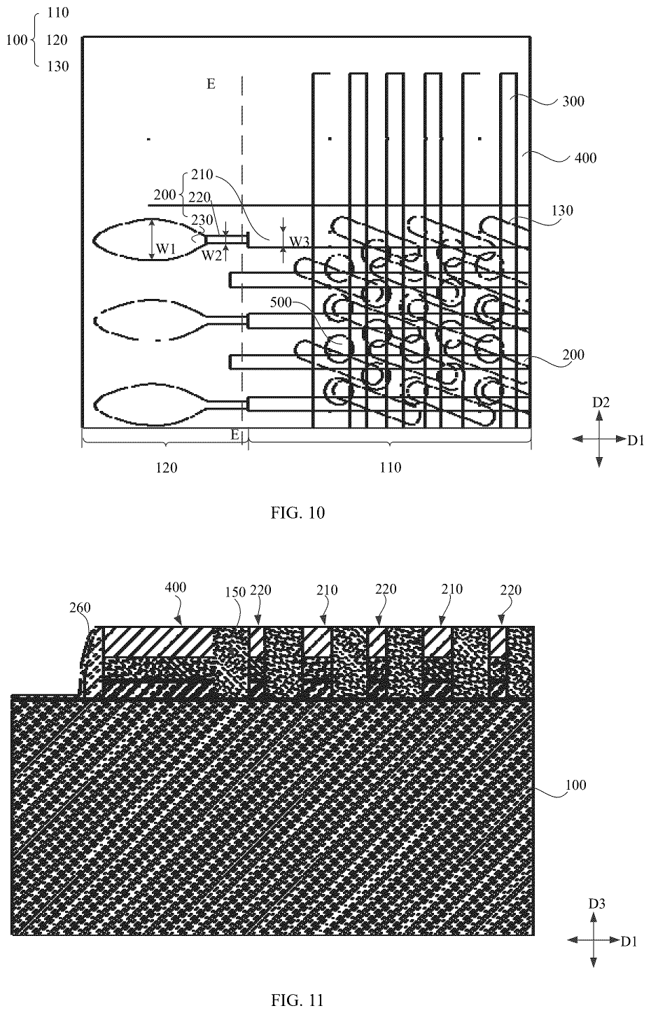

The adjacent first portions 210 may be aligned at the same end or in other ways. Please refer to FIG. 10, in two adjacent bit line structures 200, a joint between the first portion 210 and the second portion220 is staggered from an end of the first portion 210 facing away from the second portion 220. In this way, an arrangement position of each bit line structure 200 can be reasonably arranged according to the specific structure of the semiconductor structure.

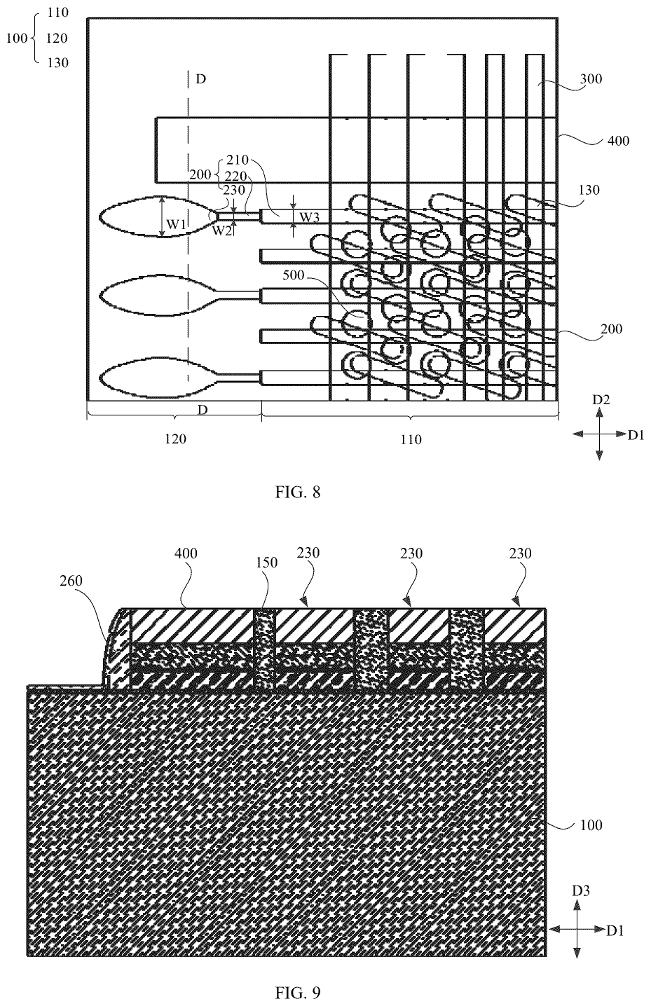

In a possible implementation, please refer to FIG. 1, FIG. 5, FIG. 8, FIG. 9, FIG. 10 and FIG. 11, the semiconductor structure further includes a dummy bit line structure 400 arranged at one side of the bit line structures 200 in the second direction D2. For example, taking an orientation shown in FIG. 1 as an example, the dummy bit line structure 400 is arranged on the bit line structures 200.

It should be understood that FIG. 9 is a sectional view along a D-D direction shown in FIG. 8, and this figure is only for illustration, and isolation sidewalls 260 on both sides of the third portion 230 are not shown. Accordingly, FIG. 11 is a sectional view along an E-E direction shown in FIG. 10. This figure is only for illustration, and an isolation sidewall on one side of the dummy bit line structure 400 and isolation sidewalls 260 on both sides of the first portion 210 and the second portion 220 are not shown.

In the first direction D1, the third portion 230 includes a first end and a second end which are oppositely arranged, and the first end is connected to the second portion 220. Referring to FIG. 5, an end of the dummy bit line structure 400 facing the third portion 230 is disposed at the joint between the first portion 210 and the second portion 220 of the bit line structure 200. Alternatively, referring to FIGS. 8 and 10, the end of the dummy bit line structure 400 facing the third portion 230 is disposed between the first end and the second end.

In other embodiments, the end of the dummy bit line structure 400 facing the third portion 230 may also be aligned with an end of the second portion 220 facing away from the first portion 210. It should be understood that the first end can be understood as an end of the third portion 230 facing the second portion 220, and the second end may be understood as an end of the third portion 230 facing away from the second portion 220.

In some embodiments, the width of the dummy bit line structure 400 in the second direction D2 is greater than the width of the bit line structure 200 in the second direction D2. In this way, the area of the dummy bit line structure 400 can be increased. The width may be the maximum width or the average width.

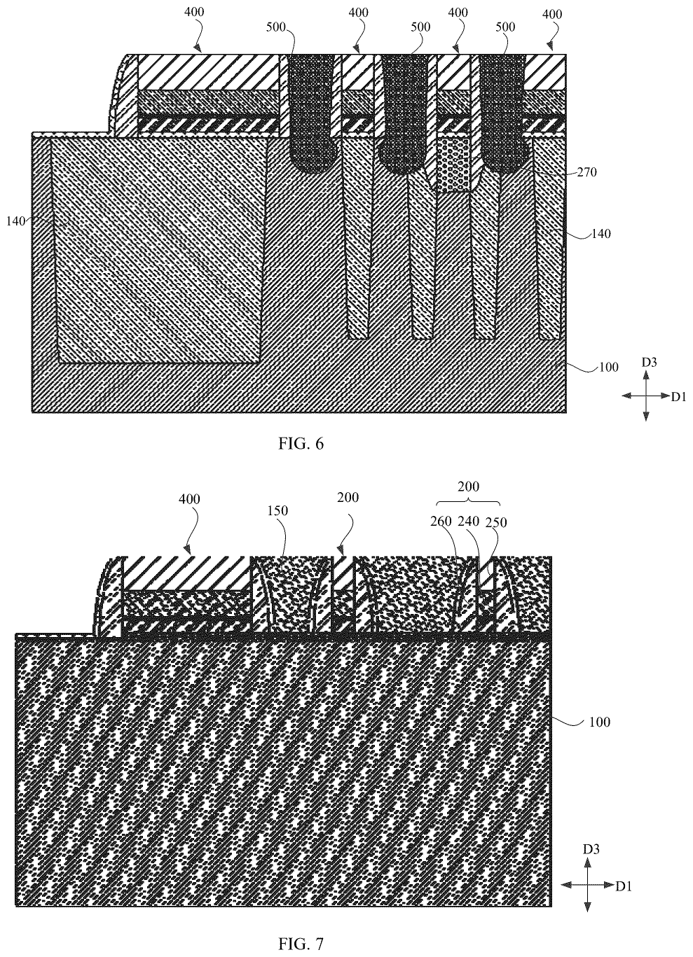

In this embodiment, the dummy bit line structure 400 and the bit line structure 200 can be formed in the same fabrication process. Please refer to FIG. 7, both the dummy bit line structure 400 and the bit line structure 200 include a bit line conductive layer 240, a bit line insulating layer 250 and an isolation sidewall 260. The bit line conductive layer 240 is arranged on the substrate 100. The bit line insulating layer 250 is arranged on the bit line conductive layer 240 to prevent the bit line conductive layer 240 from being electrically connected to other conductive component(s) arranged on the bit line insulating layer 250. The isolation sidewall 260 covers sides of the bit line conductive layer 240 and the bit line insulating layer 250 to avoid the electrical connection between adjacent bit line structures 200.

It should be noted that, in this embodiment, the bit line conductive layer 240 may have a single-layer structure or a stacked structure (such as a stacked structure of tungsten, titanium nitride, doped polysilicon, etc.). This embodiment does not specifically limit the structure. In addition, the material of the bit line insulating layer 250 includes silicon nitride, and the isolation sidewall 260 may have an “ON”structure or an “ONO structure”.

The bit line contact plug 270 is in contact with the substrate 100, thereby contributing to improving the current transmission efficiency of the semiconductor structure, reducing the power consumption, and improving the overall performance and efficiency of the semiconductor structure.

In a possible implementation, please continue to refer to FIG. 1, FIG. 2, and FIG. 6, a first contact plug 500 is arranged between first portions 210 of adjacent bit line structures 200, the first contact plug 500 may include tungsten, polysilicon, titanium nitride, or other materials. The first contact plug 500 is used to connect a capacitor (not shown in the figure) with either the source region or the drain region of the substrate 100. For example, when the first contact plug 500 is connected to the drain region of the substrate 100, correspondingly, the capacitor is also connected to the drain region of the substrate 100.

In the first direction D1, there is a fourth distance L4 between the first contact plug 500 closest to the bit line structure 200 (i.e. the first contact plug 500 disposed at the outermost edge) and the third portion 230 of the bit line structure 200, and the first contact plug 500 has a preset width W4. The fourth distance L4 is greater than 4 times the preset width W4, or a ratio of the fourth distance L4 to the preset width W4 is greater than 4.

Several insulating columns 150 are further arranged between the first contact plug 500 at the very edge and the third portion 230. Please refer to FIG. 1, in the first region, a first contact plug 500 is arranged around the first portion 210 of the bit line structure 200, while no first contact plug is arranged around the second portion 220 and the third portion 230 of the bit line structure 200, but an insulating column 150 is arranged. Therefore, it can be seen that the environment around the first portion 210 of the bit line structure 200 is different from that around the second portion 220 and the third portion 230. In order to improve the uniformity of the environment around the first portion 210, the second portion 220 and the third portion 230, in this application, the width of the third portion 230 in the second direction D2 is increased. That is, in the second direction D2, the width of the third portion 230 is greater than those of the first portion 210 and the second portion 220, and even the maximum width of the third portion 230 may be greater than the maximum width of the first contact plug 500. In this way, as the material contained in the third portion 230 is the same as that of the first contact plug 500, the uniformity of the environment around the first portion 210, the second portion 220 and the third portion 230 can be improved.

In some other embodiments, the semiconductor structure further includes a second contact plug 600. The second contact plug 600 is arranged on the first portion 210 and disposed on a side of the first portion 210 away from the second portion 220. The second contact plug 600 is used to achieve the electrical connection between the bit line structure 200 and the interconnect layer (not shown in the figure).

Compared with a technical solution in which the second contact plug 600 is arranged in the third portion 230, during the current transmission from the interconnect layer to the bit line structure 200, the current does not pass through the second portion 220 having a smaller size, thereby avoiding an increase in a resistance value during the current transmission, thereby improving the transmission efficiency of the current and reducing the power consumption due to the lower resistance value, and enhancing the overall performance and efficiency of the semiconductor structure.

The various embodiments or implementations in this description are described in a progressive manner, and each embodiment focuses on its differences from the others. The same and similar parts among the embodiments can be referred to interchangeably.

It should be noted that references to “an embodiment”, “embodiment”, “illustration embodiment”, “some embodiments” etc. in the description indicate that the described embodiments may include specific features, structures, or characteristics, but not necessarily every embodiment includes that specific features, structures, or characteristics. Furthermore, such phrases may not necessarily refer to the same embodiment. Furthermore, when describing specific features, structures, or characteristics in conjunction with embodiments, it is within the knowledge of those skilled in the art to implement such features, structures, or characteristics in conjunction with other embodiments that are explicitly or implicitly described.

Finally, it should be noted that the above embodiments are only used to illustrate the technical solution of the present application, and not to limit it. Although the present application has been described in detail with reference to the aforementioned embodiments, those skilled in the art should understand that they can still modify the technical solutions described in the aforementioned embodiments, or equivalently replace some or all of the technical features. These modifications or replacements do not make the essence of the corresponding technical solutions deviate from the scope of the technical solutions of the embodiments of the present application.

What is claimed is:

1. A semiconductor structure, comprising:
a substrate comprising an active region defined by a shallow trench isolation structure;
a plurality of word line structures disposed in the substrate, the word line structures crossing the active region and extending in a second direction;
a plurality of bit line structures disposed on the substrate and extending in a first direction, the first direction intersecting the second direction;
wherein each of the bit line structures comprises:
a first portion crossing the active region and the word line structures;
a third portion disposed on the shallow trench isolation structure;
two ends of a second portion respectively directly contact the first portion and the third portion;
wherein in the second direction, a width of the second portion is smaller than widths of the first portion and the third portion.

2. The semiconductor structure according to claim 1, wherein the width of the first portion is smaller than the width of the third portion.

3. The semiconductor structure according to claim 1, wherein the width of the first portion is a maximum width or an average width.

4. The semiconductor structure according to claim 1, wherein the width of the second portion is a maximum width or an average width.

5. The semiconductor structure according to claim 1, wherein the width of the third portion is a maximum width or an average width.

6. The semiconductor structure according to claim 1, wherein at least one side of the third portion protrudes from the second portion of the bit line structure in the second direction.

7. The semiconductor structure according to claim 1, wherein both sides of the third portion protrude from the second portion in the second direction.

8. The semiconductor structure according to claim 1, wherein along a direction perpendicular to the substrate, a top surface of the third portion is lower than a top surface of the second portion, or a top surface of the third portion is flush with a top surface of the second portion.

9. The semiconductor structure according to claim 1, wherein a shape of the third portion projected on the substrate comprises a polygon, a circle, or an ellipse.

10. The semiconductor structure according to claim 1, wherein in a direction away from the first portion of the bit line structure along the first direction, a size of the third portion in the second direction initially increases and then decreases.

11. The semiconductor structure according to claim 1, wherein at least one side of the first portion protrudes from the second portion in the second direction.

12. The semiconductor structure according to claim 1, wherein a distance between adjacent third portions is a first distance L1, and a distance between adjacent first portions is a second distance L2;
wherein the first distance L1 is greater than the second distance L2.

13. The semiconductor structure according to claim 12, wherein a ratio of the first distance L1 to the second distance L2 is 1 to 1.5.

14. The semiconductor structure according to claim 1, wherein the semiconductor structure further comprises a dummy bit line structure arranged at one side of the bit line structures in the second direction;
in the first direction, the third portion comprises a first end and a second end arranged oppositely, and the first end is connected to the second portion;
an end of the dummy bit line structure facing the third portion in the first direction is disposed at a joint between the first portion and the second portion of the bit line structure, or an end of the dummy bit line structure facing the third portion in the first direction is disposed between the first end and the second end.

15. The semiconductor structure according to claim 1, wherein a first contact plug is arranged between the first portions of adjacent bit line structures;
the first contact plug disposed at an outermost edge in the first direction has a fourth distance L4 from the third portion of the bit line structure; and the first contact plug has a preset width W4;
a ratio of the fourth distance L4 to the preset width W4 is greater than 4.

16. The semiconductor structure according to claim 1, further comprising a second contact plug, wherein the second contact plug is arranged on the first portion and disposed on a side of the first portion away from the second portion.
